(19) United States
(12) Patent Application Publication
(10) Pub. No.: US 2008/0150814 A1
(43) Pub. Date: Jun. 26, 2008

(54) Radio frequency communication analysis system

(76) Inventors: Benoit Hedou, Adrets (FR); Francis Lamotte, Crolles (FR); Thierry Thomas, Varces Allieres Et Risset (FR); Clement Zeller, Grenoble (FR)

Correspondence Address: Howard IP Law Group, P.O. Box 226, Fort Washington, PA, 19034, US

(21) Appl. No.: 11/982,742

(22) Filed: Nov. 2, 2007

(30) Foreign Application Priority Data
Nov. 3, 2006 (FR) 06/54710

(51) Int. Cl. G01R 29/08; G01R 33/00

(52) U.S. Cl. 343/703; 324/244

(57) ABSTRACT

A device for measuring variations of a magnetic field generated by a first element and likely to be modulated by this first element as well as by a second distinct element present in the field, comprising a first winding adapted to the first element and a second winding adapted to the second element, the measurement device being distinct from both elements.

### FIELD OF THE INVENTION

The present invention relates to radio-frequency communications and, more specifically, to communications between a terminal generating a magnetic field and a mobile element (transponder) present in this field. The present invention also relates to the analysis of communications between a terminal and a transponder by a device external to both elements for test purposes.

### BACKGROUND OF THE INVENTION

FIG. 1 schematically shows in the form of blocks an example of a system for analyzing communications between a reader 1 (READER) and a transponder 2 (CARD), in this example a contactless smart card.

Transponder 2 is likely to communicate contactless and wireless with terminal 1. Most often, transponder 2 has no autonomous power supply; that is, it extracts the power supply necessary to the electronic circuits that it comprises from a high-frequency field radiated by an antenna of the terminal. The operation is based on the use of oscillating circuits on the terminal side and on the transponder side. These circuits are intended to be coupled by close magnetic field (most often, with a range of less than a few tens of centimeters) when the transponder enters the field of the terminal.

The data transmission from the terminal to the card is performed by an amplitude modulation of the high-frequency excitation signal of the terminal antenna which translates as a modulation of the field that it generates. In the transponder-to-terminal direction, the transmission is performed by modulation of the impedance connected to the antenna circuit of the transponder, which translates as a modulation of the load on the field of the terminal, detectable by said terminal.

To pick up communications for test purposes, a probe 31 formed of a conductive winding placed between the two elements 1 and 2 is currently used. The signal, sensed by this winding, is analyzed by a device 3′ (ANALYZER), generally called a protocol analyzer and based on a digital processing of the signals. This analyzer is used to restore the signals exchanged between elements 1 and 2 based on measurements of the field variations.

One of the objects of protocol analyzers is to check the interoperability of the different devices. Indeed, the terminal is generally manufactured by an entity different from the transponder and different transponders are likely to operate with a same terminal and conversely. This results in a need for simulation tests, especially to control the data transfer.

The field analysis exploits the fact that the voltage available across winding 31 may be considered as proportional to the variations of the magnetic field applied to this winding.

A problem which is posed is that the reader data are more easily exploitable than the data originating from the transponder. This results among others from the fact that the amplitude of the variations imposed by the terminal is greater and thus more easily detectable than that of the variations imposed by the load.

Another problem is that the probe must disturb as little as possible the communication to obtain reliable test results.

Another problem is that when one of elements 1 and 2 modulates the magnetic field to perform a communication according to a given protocol, the response of the second element tends to disturb the interpretation of the measurements.

### SUMMARY OF THE INVENTION

One aspect of the present invention aims at overcoming all or part of the disadvantages of short-range radio-frequency communication analysis systems.

One aspect of the present invention aims at an analysis system provided with an improved measurement device.

Another aspect of the present invention provides a device for measuring variations of a magnetic field generated by a first element and likely to be modulated by this first element as well as by a second distinct element present in the field, comprising a first winding adapted to the first element and a second winding adapted to the second element, the measurement device being distinct from both elements.

According to an embodiment of the present invention, the second winding comprises at least two associated loops so that the current induced by the field of the first element changes direction from one loop to the other, the two loops being electrically in series.

According to an embodiment of the present invention, a first loop of the second winding has a shape and a size such that this loop can inscribe within the outline of a planar antenna of the second element, a second loop having a shape and a size such that it is then outside of said outline.

According to an embodiment of the present invention, the loops of the second winding have shapes and sizes such that they can inscribe within the outline of a planar antenna of the second element, one of the two loops being more central than the other with respect to this outline.

According to an embodiment of the present invention, a first loop has the approximate shape of nippers of a size such that its jaws can inscribe within the outline of the antenna of the second element, a second loop having an outline approximately inscribing within the first loop.

According to an embodiment of the present invention, the surfaces defined by the two loops are approximately equal.

According to an embodiment of the present invention, the first winding forms a nipper-shaped loop of a size such that the outline of a planar antenna of the second element is capable of inscribing between the external and internal outlines of the nipper jaws.

According to an embodiment of the present invention, the two windings are formed on a same support.

The invention also provides a system for analyzing a radio-frequency communication between a first element of transmission of a magnetic field sensed by a second element likely to modulate this field, comprising: a measurement device distinct from the two elements and provided with two windings respectively adapted to the first and to the second elements; and an analysis device provided with two acquisition paths respectively dedicated to the two windings.

According to an embodiment of the present invention, each acquisition path comprises a synchronous analog-to-digital converter.

According to an embodiment of the present invention, the system comprises a device provided with a visual indicator for aiding the positioning of at least one of the windings with respect to the second element by means of a measurement of the amplitude of the detected signal.

According to an embodiment of the present invention, the second element is a contactless smart card and the first element is a card reader.

The invention also provides a radio-frequency communication analysis method.

### BRIEF DESCRIPTION OF THE DRAWINGS

These objects, features and advantages, as well as others, of the present invention, will be discussed in detail in the following description of specific non-limiting embodiments made in relation with the appended drawings, among which:

FIG. 1 schematically shows in the form of blocks an example of a usual protocol analysis system;

FIG. 2 partially and schematically shows in the form of blocks an example of architecture of a terminal of the type to which the present invention applies;

FIG. 3 partially and schematically shows in the form of blocks an example of architecture of a transponder of the type to which the present invention applies;

FIG. 4 schematically shows in the form of blocks an embodiment of an analysis system according to the present invention;

FIG. 5 schematically shows in the form of blocks an embodiment of a portion of the system of FIG. 4;

FIG. 6 is a simplified top view of a contactless smart card;

FIG. 7 illustrates the operation of a system according to an embodiment of the present invention;

FIGS. 8A, 8B, and 8C schematically illustrate in the form of timing diagrams an example of the shape of signals at different points of an acquisition branch of the system of FIG. 4, adapted to a terminal;

FIGS. 9A, 9B, and 9C schematically illustrate in the form of timing diagrams an example of the shape of signals at different points of an acquisition branch of the system of FIG. 4, adapted to a transponder;

FIG. 10 is a top view of a probe adapted to the measurement of the field of a terminal according to an embodiment of the present invention;

FIG. 11 is a top view of a probe adapted to the measurement of the field of a smart card according to an embodiment of the present invention;

FIG. 12 shows the electric diagram of a circuit of interface between a field measurement winding and an acquisition device according to an embodiment of the present invention; and

FIG. 13 is a simplified top view of a preferred embodiment of a measurement device according to the present invention, intended for a contactless smart card.

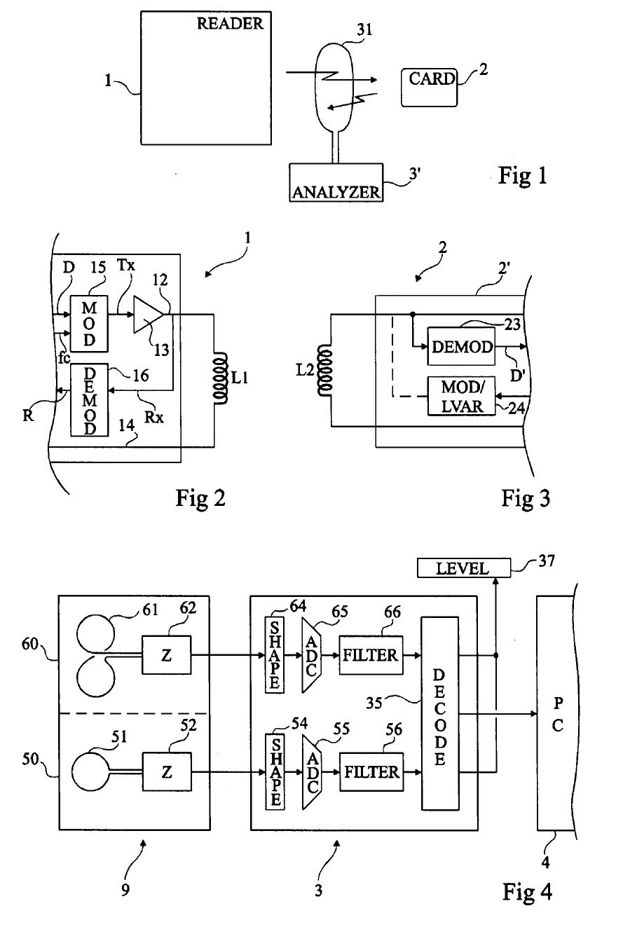

### DETAILED DESCRIPTION OF THE INVENTION

The same elements have been designated with the same reference numerals in the different drawings, which have been drawn out of scale. Further, only those elements which are useful to the understanding of the present invention have been shown and will be described. In particular, the mechanisms for coding the data to be transmitted, be it in the terminal-to-transponder or transponder-to-terminal direction, have not been detailed, the present invention being compatible with conventional protocols which are most often set by standards. Further, the exploitation after digitization of the signals obtained by the protocol analyzer has not been detailed, the invention being here again compatible with currently-used techniques.

The present invention will be described in relation with an example of a contactless smart card and of a card reader. It, however, more generally applies to any short-distance radio-frequency communication system, more specifically for remote-supplied transponders.

FIGS. 2 and 3 schematically and partially show examples of a terminal 1 and of a transponder 2.

Terminal 1 is provided with an oscillating circuit based on an antenna L1 connected to a terminal 12 of output of an amplifier or antenna coupler 13 and to a terminal 14 at a reference voltage (generally, the ground). Amplifier 13 receives a signal Tx to be transmitted which is provided by a modulator 15 (MOD). Modulator 15 mainly receives a data signal D to be transmitted and a carrier frequency fc. Signal Tx is transmitted, whether or not there are data D to be transmitted, since the magnetic field generated based on signal Tx is used as a power source by transponder 2 (FIG. 3). Data D to be transmitted generally originate from a digital system, for example, a microprocessor (not shown). The terminal also comprises a demodulator 16 (DEMOD) for detecting possible data received from transponder 2. For example, demodulator 16 receives the voltage sampled across antenna L1 (signal Rx) and the demodulator provides a received data signal R.

On the side of transponder 2 (FIG. 3), an oscillating circuit having an antenna L2 is intended to sense the field generated by the oscillating circuit of terminal 1. In this example, terminals 21 and 22 of antenna L2 are connected to an integrated circuit 2′ for exploiting the signals. This circuit comprises a demodulator 23 for demodulating the signals transmitted by the terminal. The signals originating from demodulator 23 form data signals D′ received from terminal 1 and are sent to the rest of integrated circuit 2′ comprising, for example, a microcontroller or a circuit in wired logic, having an operation clock extracted from the signal across the oscillating circuit. To transmit data to terminal 1, transponder 2 comprises an element 24 (MOD LVAR) of variable impedance capable of modifying the load formed by its own electronic circuits on its resonant circuit.

When transponder 2 is in the field of terminal 1, a high-frequency voltage is generated across its resonant circuit. This voltage, once rectified and filtered by circuit 2′, provides a supply voltage to the different electronic circuits of transponder 2. In the transponder-to-terminal direction, the modulation of the data to be transmitted is generally called a retromodulation and is performed at a rate smaller than frequency fc of excitation of the oscillating circuit of the terminal.

When retromodulation circuit 24 increases the transponder load on the oscillating circuit of the terminal, the oscillating circuit of the transponder is submitted to an additional damping with respect to the load formed by the other circuits, whereby the transponder samples a greater amount of power of the high-frequency field. On the side of terminal 1, this power variation translates as a variation of the current in antenna L1 since amplifier 13 maintains the amplitude of the high-frequency excitation signal constant or between two states set by an amplitude modulation.

In a card-to-reader communication system, the field can be split up into two components respectively due to the reader and to the transponder. A field arbitrarily called the primary field generated by the winding of the reader antenna (L1, FIG. 2) can be distinguished from a field arbitrarily called the secondary field generated by the winding of the card antenna (L2, FIG. 3). The primary field is modulated in a reader-to-card communication. The secondary field is modulated in a retromodulation (card-to-reader transmission).

The primary field generated by the reader, applied to the card, can in short-distance systems be considered as approximately homogeneous across the entire card winding. However, the secondary field cannot be considered as homogeneous close to the card.

FIG. 4 schematically shows in the form of blocks an embodiment of a system according to the present invention.

This system comprises a measurement device 9 providing signals to an analysis circuit 3 having its results, for example, stored for interpretation in a computer 4 (PC).

Measurement device 9 comprises two acquisition circuits or probes 50 and 60 respectively adapted to the signals transmitted by reader 1 and to those transmitted by card 2. Each circuit 50 or 60 comprises a conductive winding 51 and 61. The respective ends of windings 51 and 61 are connected to input terminals of circuits 52 and 62 (Z) of high impedances to avoid disturbing the communications with the measurements. The signals provided by circuits 52 and 62 are sent to circuit 3 which, according to this embodiment, comprises two parallel acquisition paths respectively dedicated to circuits 50 and 60. Each path comprises a circuit 54, 64 (SHAPE) for shaping the analog signals, by extracting the voltage representing the electromagnetic force induced in winding 51, 61, respectively. The shaping is followed by an analog-to-digital converter 55, 65 (ADC). The obtained digital signals are then submitted to a digital filtering 56, 66 (FILTER) for extracting the data from the sub-carrier. The signals representing the envelope of the modulated signals are then decoded (block 35, DECODE) to be able to interpret the exchanges between the terminal and the transponder. The objective for example is to find, in transmissions, specific communication frames between the two elements to check that standards are respected.

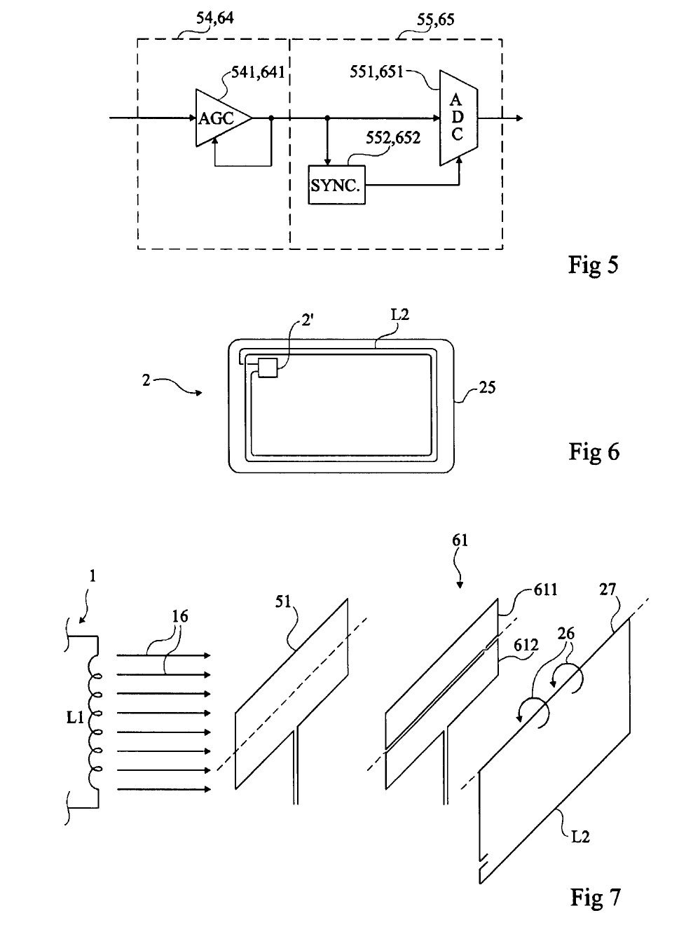

FIG. 5 schematically shows in the form of blocks an example of a shaping circuit 54 or 64 followed by an analog-to-digital converter 55 or 65.

Shaping circuit 55 or 65 mainly comprises an automatic gain control (AGC) amplifier 541 or 561 to standardize the amplitude of the carrier of the received signals. This enables, among others, compensating for the amplitude variations originating from the position of the corresponding probe in the field and operating converter 55 or 65 at full scale.

On the conversion side, the carrier of the received signal is sampled synchronously (blocks 552, 652—SYNC) to rate the actual analog-to-digital converter 551 or 651. An advantage of using a synchronous conversion is that the demodulation is performed at the same time as the digitizing of the carrier. Such synchronous converters are known per se.

FIG. 6 schematically shows an example of a smart card to which the present invention applies. Such a card is formed of a support 25, generally made of plastic matter, on or in which are incorporated one or several electronic circuits 2′. An antenna L2 formed of a planar conductive winding of one or several spirals, for example, rectangular, has its ends connected to circuit 2′.

FIG. 7 is a perspective view illustrating the operation of a system according to an embodiment of the present invention. For simplification, only the inductive windings of the different elements have been illustrated. On the side of terminal 1, antenna L1 generates a magnetic field (arrows 16) which can be considered as uniform. Card 2 senses this field due to its antenna L2. On the card side, the retromodulation can be considered as generating circular field lines (arrows 26) around the conductors of antenna L2.

Loop 51 for measuring the primary field generated by the reader is capable of exhibiting a relatively light coupling with respect to the antenna winding of the card, while exhibiting a non-negligible surface area with respect to a locally homogeneous field. Loop 61 for measuring the secondary field is capable of exhibiting a notable coupling with respect to the antenna winding of the card while exhibiting a small surface area (ideally none) with respect to a locally homogeneous field.

In this example, winding 51 of first probe 50 is formed of a loop while the winding of second probe 60 is formed of two coplanar loops 611 and 612 electrically in series and approximately forming an eight. The two probes 50 and 60 are placed between the two elements 1 and 2 (between the two antennas L1 and L2), preferably with their windings in planes parallel to the plane of antenna L2.

Winding 51 intended to sense the primary field is preferentially placed symmetrically with respect to the conductors of antenna L2 of the card. For simplification, only the case of a rectilinear section 27 of antenna L2 having its direction in the planes of windings 51 and 61 symbolized by dotted lines is here considered. By placing circular loop 51 symmetrically on the card antenna, no potential difference appears across winding 51 due to the card field. Probe 50 becomes strongly coupled to the reader. In a simplified embodiment, the loop of winding 51 has a shape and a size such that it surrounds the average spiral of the card antenna. As a variation, the loop of winding 51 may be formed of several sub-loops.

On the side of winding 61 for measuring the secondary field, forming an eight enables canceling the effects of the electromotive force induced by the primary field in this winding. The position of the winding also conditions the efficiency of the measurements. By placing it in a plane parallel to that of the card winding, the surface area exposed to the field of the reader is null. A probe of low sensitivity to the reader field, capable of selectively observing the card, is thus obtained. To increase the sensitivity to the secondary field (containing the modulation originating from the card), it is desired for loops 611 and 612 to be positioned symmetrically with respect to the conductor of the card antenna.

Different geometries may be envisaged for the two loops electrically in series forming winding 61.

For example, a first loop may be inside of the outline within which antenna L2 inscribes and a second loop may be outside as in the example illustrated in FIG. 7, but with different shapes (circular, rectangular, nippers, respectively inscribing within and around antenna L2, etc.). Due to the series electric connection and the direction inversion between the two loops so that their orientations exposed to the magnetic field of the reader are inverted, the electromotive forces induced by the reader in the two loops subtract (they cancel if their surface areas are equal) while the electromotive forces induced by the card add up.

According to other examples which will be illustrated in relation with FIGS. 11 and 13, the two loops both inscribe within the bulk of antenna L2, one of the two loops being more to the center than the other so that one of the loops is closer to antenna L2 and that the electromotive force induced by the card is greater there than that induced in the central loop, thus avoiding for the two force to compensate for each other. The electromotive forces induced by the reader in the two loops keep on compensating from each other for approximately equal surface areas.

As a variation, several sub-loops form one or the other of the loops or both, while respecting the inversion of their orientations exposed to the magnetic field of the reader.

According to a preferred embodiment of the invention, the system comprises a device 37 (LEVEL) symbolized by a block in FIG. 4, for aiding the positioning of the measurement device. Such a device 37 may be formed by means of a simple visual display (for example, a light-emitting diode rail) reflecting the amplitude of the demodulated signal originating from the respective processing paths or at least from the path dedicated to the card having the probe most sensitive to the positioning.

The dimensions of the loops of probes 51 and 61 are a function of the type of transponder, the data of which are desired to be sensed. In the case of a planar card, account is taken of the size of the average spiral (reference is made to the average spiral since the card can comprise several concentric spirals).

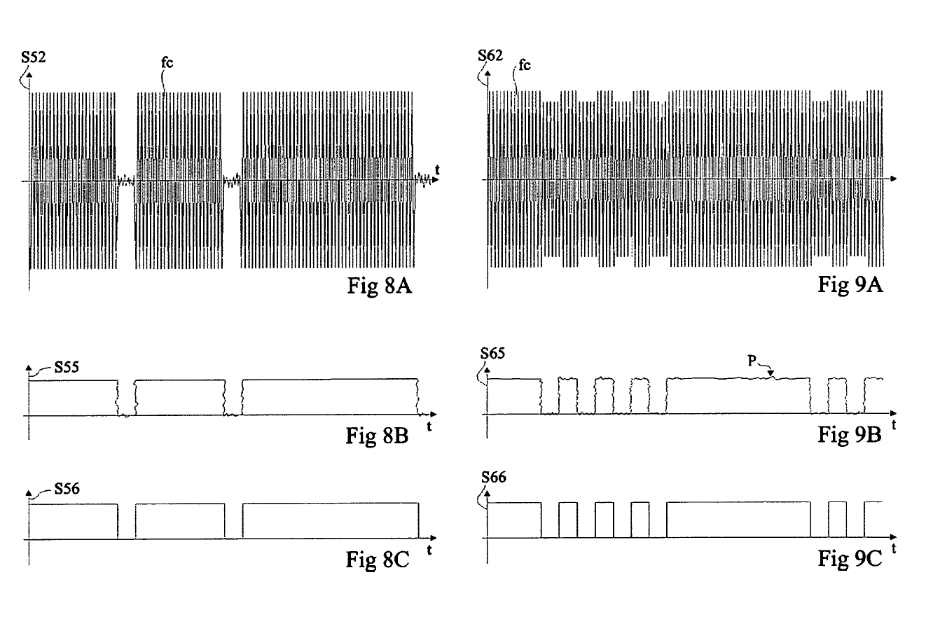

FIGS. 8A, 8B, and 8C illustrate in timing diagrams examples of shapes of signals S52, S55, and S56 obtained at the respective outputs of circuits 52, 55, and 56 of the path intended for reader 1.

FIGS. 9A, 9B, and 9C illustrate in timing diagrams examples of shapes of signals S62, S65, and S66 obtained at the respective outputs of circuits 62, 65, and 66 of the path intended for card 2. The scales of FIGS. 8 and 9 are different.

In this example corresponding to ISO standard 14443 (type A), the 13.56-MHz carrier modulation is performed by the terminal in amplitude with a 100% modulation index (modulation index=ratio between the difference and the sum of the amplitudes), that is, in all or nothing. The amplitude modulation is performed at a rate from 106 kbits/s to 847 kbits/s after coding of the data according to different protocols (in this example, a so-called Miller coding). The amplitude-modulated carrier is recovered by probe 50 which provides (output S52) an image signal of this modulation. At output S55 of the synchronous analog-to-digital converter, the carrier has been eliminated and only the modulation envelope is restored. Output S56 of filter 56 provides a less noisy digital signal, exploitable by decoder 35.

In a transmission in the card-to-reader direction, the modulation of the impedance loading the resonant circuit is performed at the rate of a retromodulation sub-carrier at 847.5 kHz (one sixteenth of the carrier at 13.56 MHz). The switching of the load modification circuit (24, FIG. 3) is, here again, generally coded. In the shown example, an amplitude modulation with a so-called Manchester coding is assumed, but other coding types (for example, BPSK) may also be used. Output S64 provides an image of the load modulation. As for the first path, at the output of the synchronous converter, the carrier at 13.56 MHz has been eliminated and only the sub-carrier envelope remains. Output S66 of filter 66 provides a less noisy digital signal, exploitable by the decoder.

Other coding (NRZ, differential phase shift, etc.) and modulations may be used, especially according to the involved standard. For example, for the type B ISO-14443 terminal, the 13.56-MHz carrier modulation is performed by the terminal in amplitude with a modulation index on the order of 10%.

Due to the probes dedicated to the primary and secondary fields, the interpretation by decoder 35 is simplified since the signals originating from the modulation on the reader side and from the modulation on the card side can be easily dissociated. In particular, a modulation of the card may be processed by the path adapted to the reader as noise since its amplitude is much lower than that of the reader. Conversely, on the side of the path adapted to the card, the fact for the contribution of the primary field to be attenuated by probe 61 enables increasing the sensitivity, and the comparison between both paths enables dissociating a modulation from possible noise.

Of course, the invention is not limited to the above modulation example. It enables recovering the modulation envelope, be this modulation in amplitude or in phase and whatever the coding used to transmit the data. The acquisition paths enable obtaining the demodulated data, the decoding and the interpretation of which are performed downstream by decoder 35 or by computer 4.

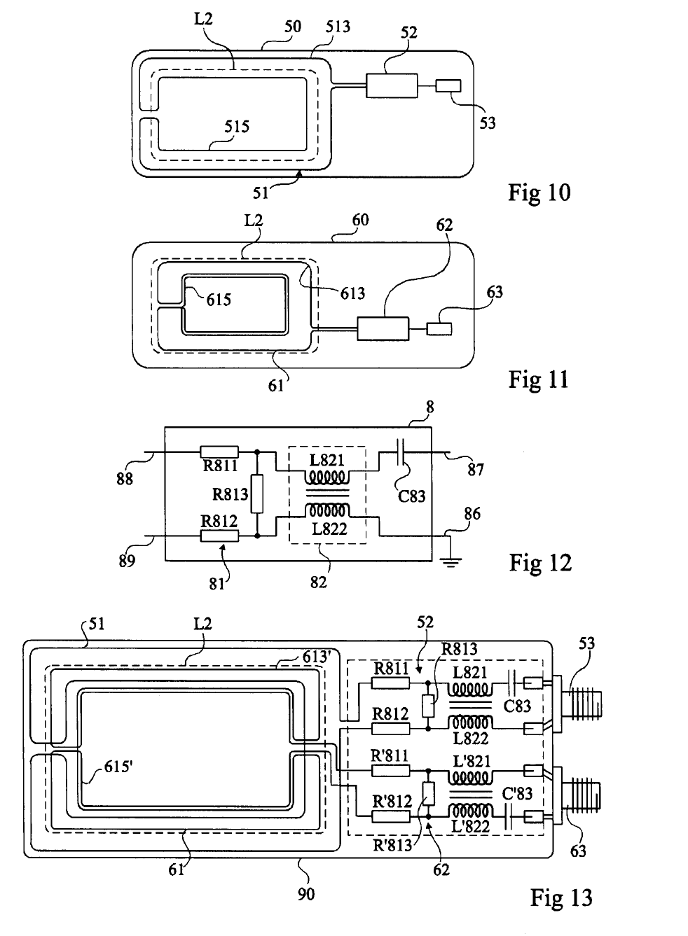

FIG. 10 schematically shows an embodiment of a probe 50 adapted to the field of the reader. This probe is for example formed on a printed circuit wafer. Winding 51 is formed of a conductive track with an outline having the general shape of nippers (of general rectangular shape) where the outside 513 of the jaws is outside of the bulk of the average spiral (dotted line referenced as L2) of the cards for which the probe is intended and where the inside 515 of the jaws is inside of this average spiral. This to respect at best the symmetry of loop 51 around the average spiral of antenna L2 when the probe is placed to be coplanar to the antenna. The two ends of winding 51 are located opposite to the opening of the nippers and are on the outside of the jaws. These ends are connected to the input of circuit 52, an embodiment of which will be described hereafter in relation with FIG. 12. Such a circuit aims at minimizing the current in the probe winding to avoid disturbing the communication. It may also perform an impedance matching and/or a switching from a symmetrical mode to an asymmetrical mode to make the signals exploitable by the downstream circuits. The output of circuit 52 is connected to a connector 53 intended to be connected to signal-processing device 3.

FIG. 11 schematically shows an embodiment of a probe 60 adapted to the card. This probe is for example also formed on a printed circuit wafer and its eight-shaped loops 61 are, preferably, formed so that their global bulk is located inside of the average spiral (dotted line referenced as L2) of the card. This results in a general nipper shape (generally rectangular) for a first loop 613 interleaved with a second loop 615 inside of the nippers, all this of course by means of a single conductor. The two ends of winding 61 are on an outer side of the first loop opposite to the nipper opening. These ends are connected to circuit 62 before the signals to be processed are provided to a connector 63 for connection to the acquisition device. The surface areas of the two loops 613 and 615 are preferably approximately equal.

FIG. 12 shows the electric diagram of a circuit 52 or 62. Such a circuit bearing reference numeral 8 in FIG. 12 comprises, between two so-called symmetrical mode input loops 88 and 89 intended to be connected across loop 51 or 61, and two so-called asymmetrical mode output terminals 87 and 86 intended to be connected to analysis circuit 3, an impedance matching circuit 81, a balun 82 and a decoupling circuit 83. For example, the impedance matching circuit is formed of three resistors R811, R812, and R813, resistors R811 and R812 having a first end connected to terminals 88 and 89 and a second end connected to the respective ends of resistor R813 and to the symmetrical mode inputs of the balun. Balun 82 is, for example, formed of two coupled inductive elements L821 and L822 having two first respective ends connected to the symmetrical mode inputs and having two respective ends defining the positive and reference terminals of the asymmetrical mode access. The two asymmetrical mode accesses of balun 82 are connected to terminals 87 and 86 (terminal 86 arbitrarily defining the ground), the access connected to terminal 87 being connected via a by-pass capacitor C83.

In the embodiment of above FIGS. 10 and 11, the two probes 50 and 60 are mechanically separated from each other, thus enabling the operator to place them between the terminal and the card in positions where it obtains, empirically, the best results for each of them. Ideally, the best sensitivity is obtained for the tested card with winding 61 sized so that its external or internal outline can be placed as close as possible to the outline of winding L2.

FIG. 13 shows a preferred embodiment of a measurement device 90 of a protocol analyzer according to the present invention. In this example, the two probes respectively dedicated to sensing the field of terminal 1 and of card 2 are supported by a same support (for example, a same printed circuit wafer). Windings 51 and 61 are, as in the embodiments of FIGS. 10 and 11 such that the average spiral (dotted lines referenced as L2) of the card family for which device 90 is intended is approximately located within the nippers forming loop 51 and is approximately located outside of the eight-shaped loops forming winding 61. Windings 51 and 61 are formed in different conductive levels, preferably, each on one surface of the wafer. Of course, a bridge or via is used for the track crossing of winding 61. As compared with FIG. 11, FIG. 13 illustrates a variation in which first loop 613′ forms nippers inside of which is drawn second loop 615′. Both ends of winding 61 are on one side of second loop 615′ corresponding to the opening side of the nippers of first loop 613′ having their jaws connected through the inside on the opposite side. As previously, the respective surface areas defined by loops 613′ and 615′ are approximately equal and these loops are electrically connected in series so that the travel direction is inverted to minimize the sensitivity with respect to the homogeneous field of the reader.

In FIG. 13, the two shaping circuits 52 and 62 have been shown by their respective equivalent electric diagrams, taking the example of circuit 8 of FIG. 12 and assigning the reference numerals with an apostrophe (′) for the components of FIG. 62. Connectors 53 and 63 are a function of the downstream circuits and, in this example, have been illustrated as coaxial cable connectors.

The device of FIG. 13 is, preferably, intended to be placed flat against card 2 with its surface comprising winding 61 on the card side, and by positioning winding 61 to be as centered as possible with respect to antenna 12 of the card to be tested. This requires for loop 613′ to have been sized to be able to be on every side as close as possible to the antenna of the cards for which the device is intended.

As a specific example of embodiment, a measurement device 90 such as illustrated in FIG. 13 has been formed, for cards having an antenna with an average spiral of a general rectangular shape with a length of approximately 68.5 mm and a width of approximately 38.5 mm, with the following dimensions: first winding 51: external width of approximately 51 mm, external length of approximately 83 mm, internal width of approximately 30 mm, internal length of approximately 60 mm, interval between jaws on the side opposite to the ends of the winding of approximately 2 mm; and second winding 61: external width of approximately 38 mm, internal length of approximately 68 mm, internal width of approximately 24 mm, internal length of approximately 54 mm, interval between jaws on the side opposite to the ends of the winding of approximately 3 mm, interval between the connection tracks on the side opposite to the ends of the winding of approximately 1 mm.

An advantage of the embodiments of the present invention is that it improves the reliability of protocol analysis systems.

Another advantage of the embodiments of the present invention is that the measurement device is easily adaptable to different families of transponders and of readers by adapting the dimensions of the two windings according to the average size of the transponder antenna.

Of course, the present invention is likely to have various alterations, modifications, and improvements which will occur to those skilled in the art. In particular, the features of the analog and digital elements are within the abilities of those skilled in the art based on the functional indications given hereabove.

Similarly, the selection between an embodiment with two windings on separate support or with a single support depends on the application and especially on the usual distance between the transponder and its reader.

Further, the signals provided by filters 56 and 66 are interpretable by usual decoders. Such decoders are formed either based on a microprocessor or in wired logic, this last embodiment being often preferred to respect processing speed needs.

Finally, if the use of two separate acquisition paths towards decoder 35 is a preferred embodiment, the multiplexing of the signals may occur upstream of the decoder, especially for half-duplex systems in which the card and the reader are not supposed to transmit at the same time.

The present invention finds many applications in transponder systems, be they so-called contactless card systems, tags, labels, etc. and be the terminal called a reader, an interrogator, etc. Different standards set operating conditions for such contactless exchange systems. As an example, ISO standards 14443, 15693, 18000-2, and 18000-3 can be mentioned.

1. A device for measuring variations of a magnetic field generated by a first element and likely to be modulated by this first element as well as by a second distinct element present in the field, comprising a first winding adapted to the first element and a second winding adapted to the second element, the measurement device being distinct from both elements.

2. The device of claim 1, wherein the second winding comprises at least two associated loops such that the current induced by the field of the first element changes direction from one loop to the other, the two loops being electrically in series.

3. The device of claim 2, wherein a first loop of the second winding has a shape and a size such that this loop can inscribe within the outline of a planar antenna of the second element, a second loop having a shape and a size such that it is then outside of said outline.

4. The device of claim 2, wherein the loops of the second winding have shapes and sizes such that they can inscribe within the outline of a planar antenna of the second element, one of the two loops being more central than the other with respect to this outline.

5. The device of claim 4, wherein a first loop has the approximate shape of nippers of a size such that its jaws can inscribe within the outline of the antenna of the second element, a second loop having an outline approximately inscribing within the first loop.

6. The device of claim 2, wherein the surfaces defined by the two loops are approximately equal.

7. The device of claim 1, wherein the first winding forms a nipper-shaped loop of a size such that the outline of a planar antenna of the second element is capable of inscribing between the external and internal outlines of the nipperjaws.

8. The device of claim 1, wherein the two windings are formed on a same support

9. A system for analyzing a radio-frequency communication between a first element of transmission of a magnetic field sensed by a second element likely to modulate this field, the system comprising:
a measurement device distinct from the two elements and provided with two windings respectively adapted to the first and the second elements; and
an analysis device provided with two acquisition paths respectively dedicated to the two windings.

10. The system of claim 9, wherein each acquisition path comprises a synchronous analog-to-digital converter.

11. The system of claim 9, comprising a device provided with a visual indicator for aiding the positioning of at least one of the windings with respect to the second element by means of a measurement of the amplitude of the detected signal.

12. The system of claim 9, wherein the measurement device measures variations of the magnetic field generated by the first element and likely to be modulated by the first element as well as by the second element.

13. The system of claim 9, wherein the second element is a contactless smart card and the first element is a card reader.
